(19) United States
(12) Patent Application Publication
(10) Pub. No.: US 2026/0267237 A1
(43) Pub. Date: Sep. 10, 2026

(54) SYSTEMS AND METHODS FOR CLAMPING A PATTERNING DEVICE IN A LITHOGRAPHY APPARATUS

(71) Applicant: ASML NETHERLANDS B.V., Veldhoven (NL)

(72) Inventor: Dirk-Jan BIJVOET, Eindhoven (NL)

(73) Assignee: ASML NETHERLANDS B.V., Veldhoven (NL)

(21) Appl. No.: 19/167,347

(22) PCT Filed: Mar. 21, 2024
(86) PCT No.: PCT/EP2024/057693

§ 371 Date: Sep. 19, 2025

Related U.S. Application Data
(60) Provisional application No. 63/458,294, filed on Apr. 10, 2023.

(51) Int. Cl. G03F 7/00

(52) U.S. Cl. CPC G03F 7/707; G03F 7/70758; G03F 7/70766; G03F 7/70783

(57) ABSTRACT

A patterning device (e.g., a reticle) is typically clamped by a vacuum clamp to a chuck in a lithography apparatus, the chuck configured to drive the patterning device in a scan direction. Acceleration of the patterning device for a scan often causes deformation of the patterning device in a corkscrew like and/or twisting shape. A new clamping system is described, which includes a vacuum clamp configured to apply a clamping force to the patterning device, and an actuator configured to apply an actuation force to the patterning device to reduce or eliminate deformation (e.g., twist deformation) imparted to the patterning device during the acceleration. The actuator is configured to apply the actuation force responsive to the acceleration.

### CROSS-REFERENCE TO RELATED APPLICATION

This application claims priority to U.S. Application No. 63/458,294 which was filed on 10 Apr. 2023, and which is incorporated herein in its entirety by reference.

### TECHNICAL FIELD

The description herein relates generally to systems and methods for clamping a patterning device in a lithography apparatus.

### BACKGROUND

A lithography (e.g., projection) apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Since, in general, the lithographic projection apparatus will have a reduction ratio M (e.g., 4), the speed F at which the substrate is moved will be 1/M times that at which the projection beam scans the patterning device.

### SUMMARY

A patterning device (e.g., a reticle) is typically clamped to a chuck in a lithography apparatus by vacuum clamps to drive the patterning device in a scan direction. Acceleration of the patterning device for a scan often causes deformation of the patterning device in an corkscrew like and/or twisting shape. A new clamping system is described (along with a corresponding method), which comprises a vacuum clamp configured to apply a clamping force to the patterning device, and an actuator configured to apply an actuation force to the patterning device to reduce or eliminate deformation (e.g., twist deformation) imparted to the patterning device during the acceleration. The actuator is configured to apply the actuation force responsive to the acceleration.

According to an embodiment, a clamping system is provided. The system comprises a vacuum clamp configured to apply a clamping force to a patterning device to clamp the patterning device during acceleration. The system comprises an actuator configured to apply an actuation force to the patterning device to reduce or eliminate deformation imparted to the patterning device during the acceleration. The actuator is configured to apply the actuation force responsive to the acceleration.

In some embodiments, the actuation force is in a direction substantially perpendicular to a direction of the acceleration.

In some embodiments, the patterning device comprises a reticle.

In some embodiments, the deformation imparted to the patterning device during acceleration comprises twist deformation.

In some embodiments, the patterning device has a rectangular shape, the vacuum clamp further comprises two supports for a first side of the patterning device and one support for a second side of the patterning device, the twist deformation occurs on the second side of patterning device, and the actuation force is configured to reduce or eliminate the twist deformation on the second side of the patterning device.

In some embodiments, the actuation force applied by the actuator does not suppress deformation due to frictional forces from the vacuum clamp caused by the acceleration.

In some embodiments, the vacuum clamp comprises a reticle vacuum clamp for a deep ultraviolet (DUV) lithography apparatus.

In some embodiments, the actuator is configured such that the actuation force comprises a pushing force configured to be applied to a first portion of the patterning device, and a pulling force configured to be applied to a second portion of the patterning device.

In some embodiments, the vacuum clamp comprises a vacuum pad. The actuator is configured to act on the pad such that the pad applies the actuation force to the patterning device, or the actuator is configured to act directly on the patterning device to apply the actuation force.

In some embodiments, the actuator is a Lorentz force based actuator. In some embodiments, the actuator is a piezoelectric actuator.

In some embodiments, the actuator is an air pump configured to pressurize a gap between the patterning device and a vacuum pad of the vacuum clamp; or an air pump or air bearing configured to act on the vacuum pad, between the vacuum pad and a reticle chuck. In some embodiments, the air pump is configured to cause a pressure gradient in the gap such that a pushing force is applied to a first portion of the patterning device, and a pulling force is applied to a second portion of the patterning device. The pushing force and the pulling force together comprise the actuation force.

In some embodiments, the system comprises one or more processors. The one or more processors are configured by machine-readable instructions to determine that the patterning device is accelerating, and responsive to a determination of acceleration, cause the actuator to apply the actuation force to the patterning device to reduce or eliminate the deformation imparted to the patterning device.

In some embodiments, the system comprises one or more sensors configured to generate output signals conveying information related to the acceleration of the patterning device. In some embodiments, the one or more processors are configured to determine that the patterning device is accelerating based on the output signals.

In some embodiments, the actuator comprises a rotatable coupling. In some embodiments, the rotatable coupling comprises a rotatable yoke. In some embodiments, the rotatable coupling comprises two supports configured to contact the patterning device. The rotatable coupling is configured to rotate in response to the acceleration of the patterning device.

In some embodiments, a center of gravity reaction mass of the rotatable coupling is aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, thereby counteracting patterning device deformation.

According to another embodiment, a clamping method is provided. The method is performed by the clamping system, and includes one or more of the operations described above.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts.

FIG. 1 schematically depicts a lithography apparatus, according to an embodiment.

FIG. 2 schematically depicts an embodiment of a lithographic cell or cluster, according to an embodiment.

FIG. 3A illustrates a lithographic apparatus including a reticle handler turret gripper, reticle stage reticle clamps, and/or other components, according to an embodiment.

FIG. 3B is an enlarged view of a portion of the lithographic apparatus shown in FIG. 3A, according to an embodiment.

FIG. 4 illustrates a perspective view of a prior clamping system, according to an embodiment.

FIG. 5 illustrates a side view (in the x direction from FIG. 4) of the prior clamping system, according to an embodiment.

FIG. 6 illustrates twist or corkscrew deformation of a patterning device, according to an embodiment.

FIG. 7 illustrates an example embodiment of the (present) clamping system, according to an embodiment.

FIG. 8 illustrates a side view (in the x direction from FIG. 7) of an example embodiment of the present clamping system, according to an embodiment.

FIG. 9 shows an example actuator of the present clamping system comprising a rotatable coupling, according to an embodiment.

FIG. 10 illustrates a clamping method, according to an embodiment.

FIG. 11 is a block diagram of an example computer system, according to an embodiment.

### DETAILED DESCRIPTION

In general, a mask or reticle (e.g., a patterning device) may be a transparent block of material that is covered with a pattern defined by a different, opaque material. Various masks are fed into a lithographic apparatus and used to form layers of a semiconductor device. Clamps (e.g., reticle stage reticle clamps) in the lithographic apparatus are used to secure the masks or reticles during processing. The clamps accelerate in an x and/or y direction, and drive the reticle in a lithographic apparatus scan direction during processing. The reticle is typically supported by three supports protruding from the clamps in a z direction-one support in one clamp on one side of the reticle, and two supports in a second clamp on the other side of the reticle. This design allows the reticle to flex or bend as needed to maintain its own shape. However, this design also causes the reticle to deform during acceleration in a corkscrew or twisting shape, which hampers process accuracy, among other detrimental effects.

Advantageously, the present systems and methods suppress (e.g., reduce and/or otherwise eliminate) this corkscrew or twisting deformation during acceleration. The present systems and methods introduce out of plane actuation z forces at the clamp with the single z support, which suppress the corkscrew or twisting deformation. These actuation z forces may be introduced actively via an actuator actively pushing and/or pulling on a vacuum pad or protruding from the vacuum pad and acting directly on the reticle, or passively by replacing the one support with a rotatable yoke having two z supports. In the passive embodiment, the center of gravity of the yoke is below a pivot of the rotatable yoke, such that during acceleration, the inertia of the yoke causes a rotation around the pivot point, thus counteracting the reticle deformation, as described below.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively. In addition, any use of the terms “reticle” or “mask” herein may be considered synonymous with the more general term “patterning device.”

As an introduction, prior to transferring a pattern from a patterning device such as a mask to a substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement and/or other inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing. The individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc.

Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1λ)/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

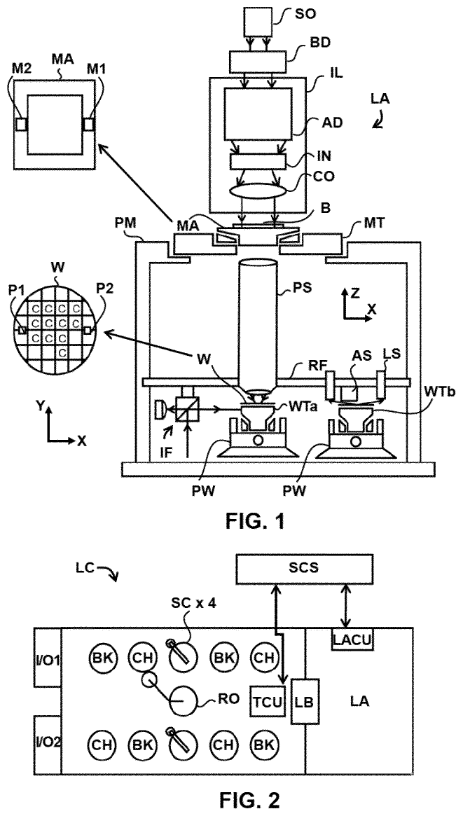

FIG. 1 schematically depicts an embodiment of a lithographic apparatus LA that may be included in and/or associated with the present systems and/or methods. The apparatus comprises: an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The projection system PS has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e. the plane of the patterning device MA), through the projection system PS and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two dimensional grid, in an image plane of the projection system (i.e. the substrate table WTa or WTb) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e. the plane of the patterning device MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system.

Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g., an interferometric device, linear encoder, 2-D encoder, or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. 3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above. Combinations and/or variations on the above-described modes of use or entirely different modes of use may also be employed.

A substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, critical dimension (CD), edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

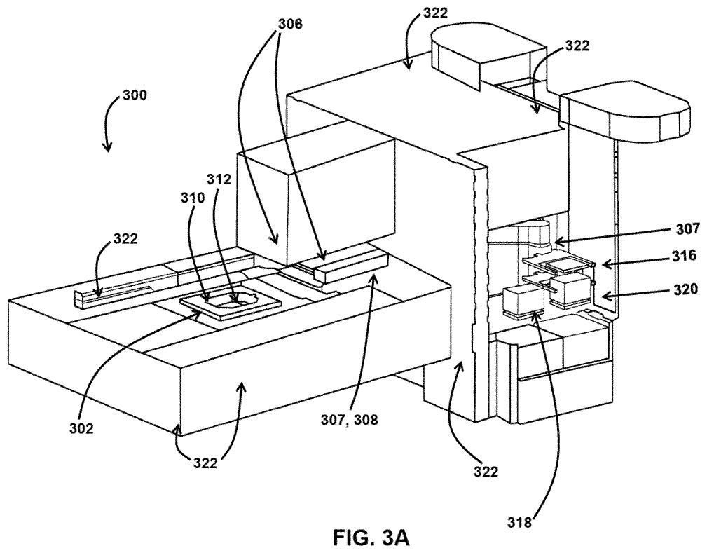

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. For example, contamination on reticle clamp membranes (e.g., as described herein) may adversely affect overlay because clamping a reticle over such contamination will distort the reticle. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

A metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques.

The present systems, and/or methods may be used as stand-alone tools and/or techniques, and/or or used in conjunction with other semiconductor manufacturing processes, to enhance the accurate transfer of complex designs to physical wafers.

As described above, the present clamping system comprises a vacuum clamp configured to apply a clamping force to the patterning device, and an actuator configured to apply an actuation force to the patterning device to reduce or eliminate deformation (e.g., twist deformation) imparted to the patterning device during acceleration associated with scanning for lithography. The actuator is configured to apply the actuation force responsive to the acceleration. The patterning device may be a reticle and/or other patterning devices. The vacuum clamp may comprise a reticle vacuum clamp for a deep ultraviolet (DUV) lithography apparatus, for example.

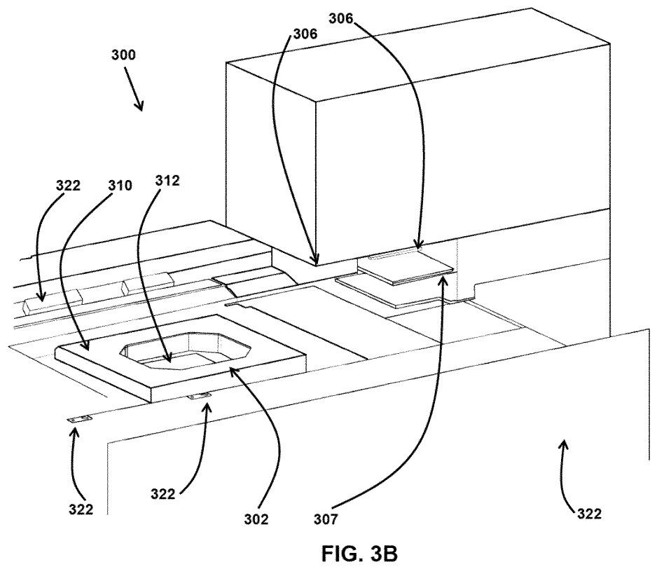

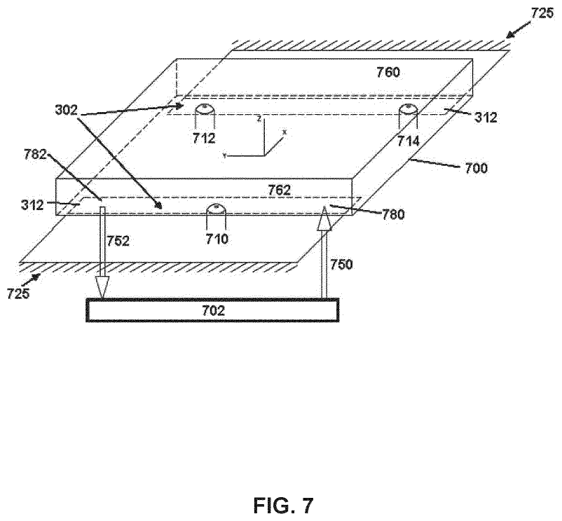

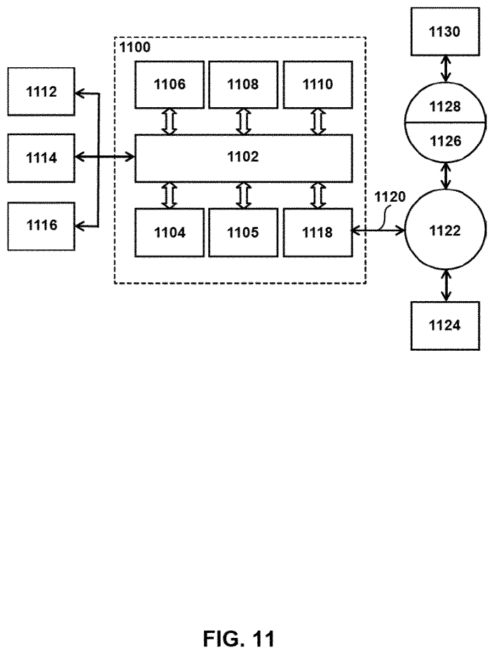

By way of a non-limiting example, FIGS. 3A and 3B illustrate (a portion of) a lithographic apparatus 300 (e.g., similar to an or the same as the lithographic apparatus shown in FIG. 1). Lithographic apparatus 300 may use a patterning device such as a reticle to pattern a substrate such as a semiconductor wafer to form semiconductor devices. FIG. 3A illustrates various components of lithographic apparatus 300 including a tool handler 306, 307, 308, reticle stage 310 and reticle clamps 312 (only one side is visible in FIG. 3A) which form a portion of the present clamping system 302, and/or other components. In some embodiments, lithographic apparatus 300 is configured for deep ultraviolet (DUV) lithography. In some embodiments, a similar apparatus may be configured for extreme ultraviolet (EUV) lithography. In some embodiments, clamping system 302 comprises a reticle stage 310, reticle clamps 312 (e.g., a vacuum clamp), an actuator (see FIG. 7-9), or more processors and/or computing system described herein (see FIG. 11), one or more (e.g., acceleration) sensors, and/or other components. These components are described in turn, below.

In some embodiments, tool handler 306, 307, 308 comprises a reticle handler turret gripper 306, a reticle handler robot gripper 307 (having associated clamps 308, etc. for gripping a reticle), and/or other components. Reticle handler robot gripper 307 may, for example, move a reticle from a pod 320 (e.g., after a user places a reticle in pod 320). Reticle handler turret gripper 306 may, for example, move a reticle from reticle handler robot gripper 307 to reticle clamps 312. Lithographic apparatus 300 may include various other mechanical components 322 (translation mechanisms, elevation mechanisms, rotational mechanisms, motors, power generation and transmission components, structural components, etc.) configured to facilitate movement and control of a reticle through lithographic apparatus 300.

FIG. 3B is an enlarged view of a portion of lithographic apparatus 300. FIG. 3B shows clamping system 302, reticle handler turret gripper 306, reticle stage 310, reticle stage reticle clamps 312 (only one side is visible in FIG. 3B), mechanical components 322, reticle handler robot gripper 307, and/or other components. As shown in FIG. 3B, reticle handler turret gripper 306 is configured to move a reticle from reticle handler robot gripper 307 to reticle clamps 312 so clamping system 302 can be used to clamp the reticle. Moving a reticle may comprise moving the reticle toward or away from the membranes and clamps 312 in horizontal, vertical, and/or other directions. Reticle handler turret gripper 306 and/or reticle handler robot gripper 307 may include various motors, translators, rotational components, clamps, clips, power sources, power transmission components, vacuum mechanisms, and/or other components that facilitate the movement of a reticle.

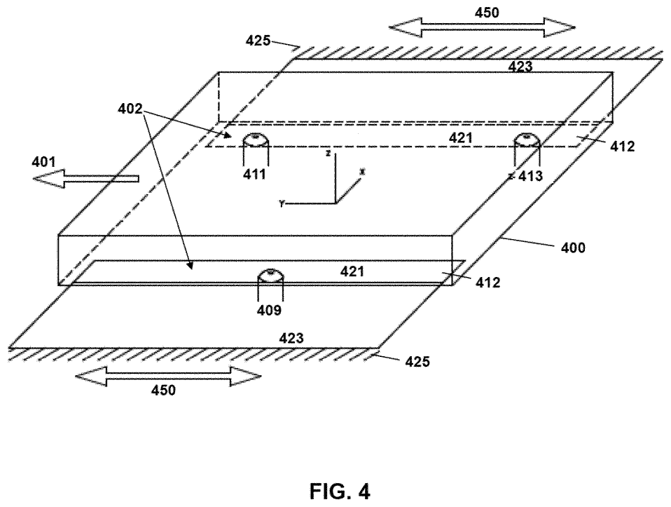

FIG. 4 illustrates a perspective view of a prior clamping system 402, according to an embodiment. System 402 is shown clamping a patterning device 400 such as a reticle and/or other patterning devices. System 402 comprises reticle clamps 412, which may be vacuum clamps, for example and/or other components. Clamps 412 may comprise thin Zerodur (or similar) membranes having a vacuum clamp pad on one side 421 (at which patterning device 400 is clamped), with its other side 423 attached to a (e.g., reticle stage short stroke) chuck 425, for example.

Clamps 412 in a lithographic apparatus are used to secure patterning device 400 during processing. A clamping force (e.g., by way of a vacuum) is applied to patterning device 400 with reticle (vacuum) clamps 412 to clamp patterning device 400 during acceleration 401 (in a left—y-direction in the example shown in FIG. 4). The reticle (vacuum) clamps 412 may be part of a DUV lithography apparatus, as described above. Acceleration 401 may be associated with movement of patterning device 400 for a lithography operation. For example, FIG. 4 illustrates a chuck 425 movement (scan) direction 450 (back and forth in the y direction in this example).

In some embodiments, as shown in FIG. 4, patterning device 400 has a rectangular shape.

Patterning device 400 is supported by three supports 409, 411, and 413 protruding through and/or from the clamps 412 in a z direction—one support 409 in one clamp 412 on one side of patterning device 400, and two supports 411 and 413 in a second clamp 412 on the other side of patterning device 400.

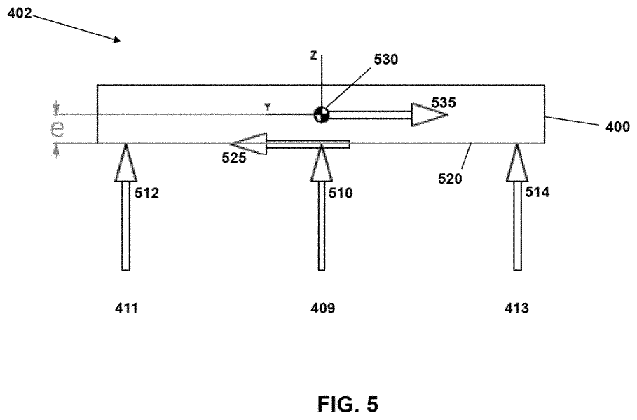

FIG. 5 illustrates a side view (in the x direction from FIG. 4) of the prior clamping system 402. Forces acting on patterning device 400 during acceleration are shown. FIG. 5 illustrates reaction forces 510, 512, and 514 from supports 409, 411, and 413, respectively, acting on a (bottom) side 520 of patterning device 400. Patterning device 400 is driven by the chuck (e.g., chuck 425 shown in FIG. 4) in the scan direction (401 in FIG. 4) by means of a friction force 525 from (vacuum) clamps 312 (FIG. 4) clamping patterning device 400 on (one) side 520 (e.g., the reflective side of a reticle). There is an offset e between a center of gravity/point of inertia 530 of patterning device 400 and side 520, where patterning device 400 is clamped and drive/scan forces are applied (via the frictional force from clamps 312). The offset e is approximately half of the thickness of patterning device 400. Because of this, there is an inertial force 535 in the opposite direction of friction force 525. In combination, these forces cause patterning device 400 to deform in a twisting or corkscrew direction (the x direction in this example) during acceleration for scanning.

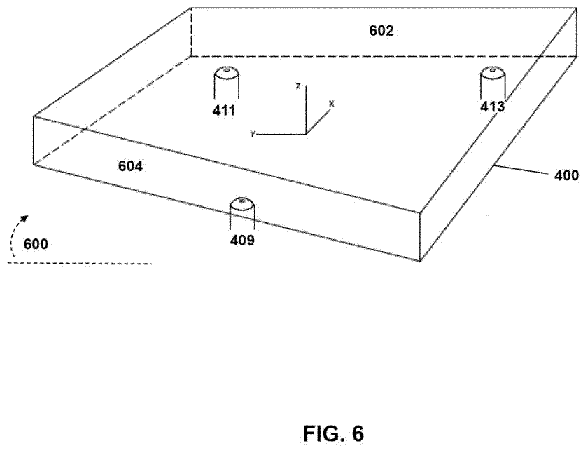

FIG. 6 illustrates an example of twist or corkscrew deformation 600 of patterning device 400. As described above, the (vacuum) clamp(s) 412 (see FIG. 4) comprise two supports 411 and 413 for a first side 602 of patterning device 400 and one support 409 for a second side 604 of patterning device 400. The twist deformation occurs on second side 604 of patterning device 400 during acceleration. Deformation 600 can be on the order of greater than about 80 nm (as one possible example) out of plane (e.g., out of the plane formed by patterning device 400), and greater than about 66 nm (again as one possible example) in plane.

In a prior scan motion profile, an acceleration force was reduced to zero and no scan forces were acting on patterning device 400 when exposure (e.g., associated with lithography) started. Although there were no acceleration forces acting on patterning device 400, patterning device 400 was still often deformed as a response to a scan process set point (due to its eigenfrequency). To reduce residual twist or corkscrew deformation, prior clamps 412 were often configured provide a damping functionality for damping the deformation to an acceptable value before starting scanning. However, this has disadvantages. For example, the damping of patterning device 400 deformation to an acceptable level takes time which can limit the throughput of the lithography apparatus.

To resolve these and other issues, in more recent scan motion profiles, the acceleration phase of patterning device 400 continues during exposure. However, patterning device 400 deforms during exposure, as described above. The present systems and methods are configured to correct for deformation caused by acceleration during exposure, and/or other deformation. The corkscrew or twist deformation 600 of a patterning device during acceleration phase is suppressed (e.g., reduced and/or eliminated) by introducing out of plane forces under the clamp comprising the single z-support.

FIG. 7 illustrates an example embodiment of (present) clamping system 302. System 302 is shown clamping a patterning device 700 such as a reticle and/or other patterning devices. For simplicity and to facilitate the discussion below, FIG. 7 illustrates patterning device 700 as a single block of material shaped as a rectangular prism. In some embodiments, some or all of patterning device 700 may be formed from an opaque, transparent, or nearly transparent material such as ultra-low thermal-expansion quartz (SFS), a transparent material such as glass, an opaque material such as metal, a polymer, a ceramic, and/or other materials. Fabrication of patterning device 700 can utilize any number of materials.

System 302 comprises reticle clamps 312, an actuator 702, and/or other components. Clamps 312 may be vacuum clamps, for example. Clamps 312 may comprise thin Zerodur (or similar) membranes having a vacuum clamp pad on one side (at which patterning device 700 is clamped), with its other side attached to a (e.g., reticle stage short stroke) chuck 725. In some embodiments, clamping system 302 includes and/or is configured to communicate with one or more sensors, one or more processors and/or a computing system as described below (see FIG. 11), and/or other components. The various components of clamping system 302 may be coupled in any arrangement and using any coupling components that allow clamping system 302 to function as described herein.

In a lithographic apparatus (see FIGS. 3A and 3B), clamps 312 are used to secure patterning device 700 during processing. A clamping force (e.g., by way of a vacuum) is applied to patterning device 700 with reticle (vacuum) clamps 312 to clamp patterning device 700 during acceleration (in a left or right—y-direction in the example shown in FIG. 7). The reticle (vacuum) clamps 312 may be part of a DUV lithography apparatus, as described above. The acceleration may be associated with movement of the patterning device for a lithography operation, for example.

Patterning device 700 is supported by three supports 710, 712, and 714 protruding through and/or from the clamps 312 in a z direction—one support 710 in one clamp 312 on one side of patterning device 700, and two supports 712 and 714 in a second clamp 312 on the other side of patterning device 700. As described above, this design still allows patterning device 700 to flex or bend as needed to maintain its own shape.

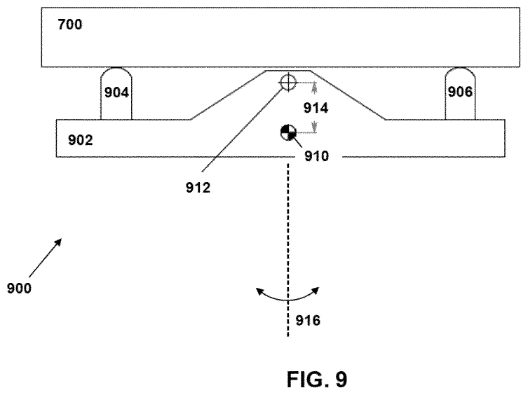

Clamping system 302 is configured to suppress (e.g., reduce and/or otherwise eliminate) any corkscrew or twisting deformation (see FIG. 6) in patterning device 700 during acceleration. Actuator 702 is configured to introduce out of plane actuation z forces 750 and 752 at the clamp 312 with the single z support 710, which suppresses the corkscrew or twisting deformation. These actuation z forces 750 and 752 may be introduced actively via actuator 702 actively pushing and/or pulling on a vacuum pad of clamp 312, or protruding from the vacuum pad and acting directly on patterning device 700. These actuation z forces 750 and 752 may be introduced passively by replacing the one support 710 with a rotatable yoke having two z supports (e.g., as shown in FIG. 9 and described below).

Actuator 702 is configured to apply the actuation force (e.g., out of plane actuation z forces 750 and 752) responsive to the acceleration. As shown in FIG. 7, out of plane actuation z forces 750 and 752 (e.g., the actuation force) may be in a z direction substantially perpendicular to a y direction of the acceleration (left or right in this figure). Actuator 702 may comprise a motor, one or more moveable actuation elements, a pump, one or more processors (e.g., which may function as a controller for the actuator), electrical components, and/or other components. For example, in some embodiments, actuator 702 may be and/or include a Lorentz force based actuator, a piezoelectric actuator, an air pump, an air bearing, a rotatable coupling (e.g., as shown in FIG. 9 and described below), and/or other actuators.

In some embodiments, as shown in FIG. 7, patterning device 700 has a rectangular shape, the (vacuum) clamp(s) 312 comprises two supports 712 and 714 for a first side 760 of patterning device 700 and one support 710 for a second side 762 of patterning device 700, the twist deformation occurs on second side 762 of patterning device 700, and the actuation force (e.g., out of plane actuation z forces 750 and 752) is configured to reduce or eliminate the twist deformation on second side 762 of patterning device 700. In some embodiments, the (vacuum) clamp 312 comprises a vacuum pad, and actuator 702 is configured to act on the pad such that the pad applies the actuation force to patterning device 700. In some embodiments, actuator 702 is configured to act directly on patterning device 700 to apply the actuation force.

In some embodiments, as shown in FIG. 7, actuator 702 is configured such that the actuation force comprises a pushing (actuation z) force 750 configured to be applied to a first portion 780 of patterning device 700, and a pulling (actuation z) force 752 configured to be applied to a second portion 782 of patterning device 700. For example, actuator 702 may be an air pump configured to pressurize a gap between patterning device 700 and a vacuum pad of (vacuum) clamp 312. As another example, actuator 702 may be an air pump or air bearing configured to act on the vacuum pad, between the vacuum pad and a reticle chuck (e.g., chuck 725). The air pump may be configured to cause a pressure gradient in the gap such that pushing (actuation z) force 750 is applied to first portion 780 of patterning device 700, and pulling (actuation z) force 752 is applied to second portion 782 of patterning device 700. The pushing force 750 and the pulling force 752 together may comprise the actuation force, for example.

In some embodiments, one or more processors (see FIG. 11) are operatively coupled to actuator 702 and configured to determine that patterning device 700 is accelerating (in the y direction in this example). Responsive to a determination of acceleration, the one or more processors may cause actuator 702 to apply the actuation force (e.g., 750, 752) to patterning device 700 to reduce or eliminate the (e.g., twist or corkscrew) deformation imparted to patterning device 700. For example, one or more sensors included in a lithography apparatus may generate output signals conveying information related to the acceleration of patterning device 700. The one or more sensors may comprise one or more accelerometers, for example, and/or other sensors. The one or more processors may be configured to determine that patterning device 700 is accelerating based on the output signals and/or other information. In some embodiments, the one or more processors may determine that patterning device 700 is accelerating based on an instruction and/or command provided by and/or otherwise associated with a lithography apparatus, and/or other information.

In some embodiments, the one or more processors and/or the one or more sensors may be included in lithographic apparatus 300 (FIGS. 3A, 3B), for example, and/or be associated with control software running on lithographic apparatus 300. The one or more processors are configured by machine-readable instructions. Communication may be wired and/or wireless, for example, as described below (in conjunction with FIG. 11). One or more processors may facilitate receiving entry and/or selection of control commands from the user via a user interface. These control commands may be received in real time or near real time. In some embodiments, the control commands comprise adjustments to a scan movement profile, for example, forces provided by actuator 702, and/or other control commands.

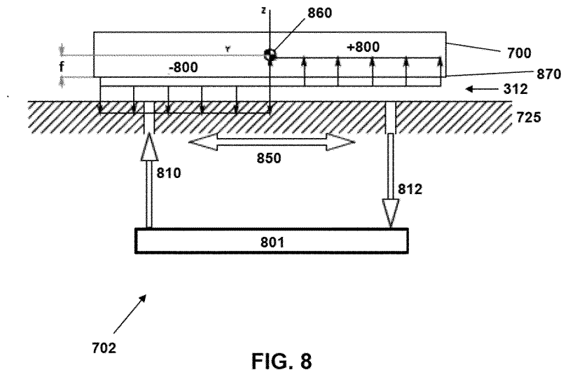

FIG. 8 illustrates a side view (in the x direction from FIG. 7) of an example embodiment 801 of actuator 702 (FIG. 7) of clamping system 302 (FIG. 7). FIG. 8 illustrates a pressure gradient +800 and −800 between the underside of a vacuum pad of (vacuum) clamp 312 and chuck 725. The pressure gradient +800 and −800 is configured to apply a counteracting force/torque 810, 812 to patterning device 700 to suppress patterning device 700 deformation during acceleration. The acceleration corresponds to chuck 725 movement (scan) direction 850 (back and forth in the y direction in this example). In this example, actuator 702 may be formed by an air pump, for example.

An offset f between a center of gravity/point of inertia 860 of patterning device 700 and (bottom) side 870, where patterning device 700 is clamped and drive/scan forces are applied (via the frictional force from clamps 312), is shown. The offset f is again approximately half of the thickness of patterning device 700. However, pressure gradient +800 and −800 is configured to counteract forces that may cause deformation in patterning device 700 in the twisting or corkscrew direction (the x direction in this example) during acceleration for scanning.

FIG. 9 shows another example embodiment 900 of actuator 702 (FIG. 7) of the present clamping system 302 (FIG. 7). Embodiment 900 comprises a rotatable coupling 902 and/or other components. Rotatable coupling 902 comprises a rotatable yoke, for example, as shown in FIG. 9. In some embodiments, rotatable coupling 902 (e.g., the rotatable yoke) comprises two supports 904 and 906 configured to contact patterning device 700. Rotatable coupling 902 is configured to rotate in response to the acceleration of patterning device 700 (e.g., without a need for processors and/or sensors). For example, a center of gravity reaction mass 910 of rotatable coupling 902 may be aligned with a pivot point reaction mass 912 of rotatable coupling 902, and spaced from pivot point reaction mass 912 by a target distance 914 along an axis of rotation 916. During acceleration of patterning device 700, inertia of rotatable coupling 902 causes rotation of rotatable coupling 902 around pivot point reaction mass 912 and axis of rotation 916, thereby counteracting patterning device deformation. Thus, again in this embodiment 900, actuator 702 is configured to apply the actuation force responsive to the acceleration.

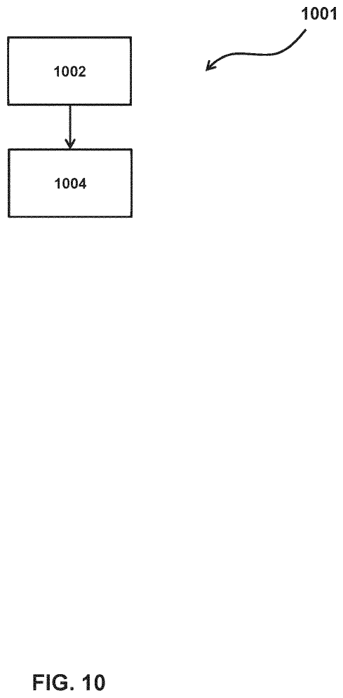

FIG. 10 illustrates a clamping method 1001. Method 1001 may be performed with a clamping system, as described above, for example. In some embodiments, the clamping system includes and/or is configured to communicate with one or more processors and/or a computing system, as described below (see FIG. 11). The operations of method 1001 presented below are intended to be illustrative. In some embodiments, method 1001 may be accomplished with one or more additional operations not described, and/or without one or more of the operations discussed. Additionally, the order in which the operations of method 1001 are illustrated in FIG. 10 and described below is not intended to be limiting.

In some embodiments, one or more portions of method 1001 may be implemented in and/or controlled by one or more processing devices (e.g., a digital processor, an analog processor, a digital circuit designed to process information, an analog circuit designed to process information, a state machine, and/or other mechanisms for electronically processing information, as described with respect to FIG. 11 below). The one or more processing devices may include one or more devices executing some or all of the operations of method 1001 in response to instructions stored electronically on an electronic storage medium. The one or more processing devices may include one or more devices configured through hardware, firmware, and/or software to be specifically designed for execution of one or more of the operations of method 1001 (e.g., see discussion related to FIG. 11 below). For example, the one or more processing devices may detect acceleration of a patterning device based on information in sensor output signals, and cause the actuator to apply the actuation force.

At an operation 1002, a clamping force is applied to a patterning device with a vacuum clamp to clamp the patterning device during acceleration. The patterning device may be a reticle and/or other patterning devices. The vacuum clamp may be part of a lithography apparatus. In some embodiments, the lithography apparatus is configured for DUV or EUV radiation. For example, the vacuum clamp may comprise a reticle vacuum clamp for a deep ultraviolet (DUV) lithography apparatus. The acceleration may be associated with movement of the patterning device for a lithography operation, for example. In some embodiments, operation 1002 is performed by a vacuum clamp of a lithography apparatus similar to and/or the same as the vacuum clamp shown in FIGS. 3A, 3B, 7, 8, etc., and described herein, and/or other components.

Operation 1004 comprises applying, with an actuator, an actuation force to the patterning device to reduce or eliminate deformation imparted to the patterning device (e.g., twist deformation and/or other deformation) during the acceleration. The actuator is configured to apply the actuation force responsive to the acceleration. The actuation force may be in a direction substantially perpendicular to a direction of the acceleration. In some embodiments, actuator is the same as or similar to the actuator shown in FIGS. 7, 8, and/or 9, and described herein). For example, the actuator may be a Lorentz force based actuator, a piezoelectric actuator, an air pump, an air bearing, a rotatable coupling, and/or other actuators.

In some embodiments, the patterning device has a rectangular shape, the vacuum clamp comprises two supports for a first side of the patterning device and one support for a second side of the patterning device, the twist deformation occurs on the second side of patterning device, and the actuation force is configured to reduce or eliminate the twist deformation on the second side of the patterning device. In some embodiments, the vacuum clamp comprises a vacuum pad, and the actuator is configured to act on the pad such that the pad applies the actuation force to the patterning device, or the actuator is configured to act directly on the patterning device to apply the actuation force.

In some embodiments, the actuator is configured such that the actuation force comprises a pushing force configured to be applied to a first portion of the patterning device, and a pulling force configured to be applied to a second portion of the patterning device. For example, the actuator may be an air pump configured to pressurize a gap between the patterning device and a vacuum pad of the vacuum clamp; or an air pump or air bearing configured to act on the vacuum pad, between the vacuum pad and a reticle chuck. The air pump may be configured to cause a pressure gradient in the gap such that a pushing force is applied to a first portion of the patterning device, and a pulling force is applied to a second portion of the patterning device. The pushing force and the pulling force together may comprise the actuation force, for example.

In some embodiments, operation 1004 comprises determining, with one or more processors configured by machine-readable instructions, that the patterning device is accelerating. Responsive to a determination of acceleration, the one or more processors may cause the actuator to apply the actuation force to the patterning device to reduce or eliminate the deformation imparted to the patterning device. For example, one or more sensors may generate output signals conveying information related to the acceleration of the patterning device. The one or more processors may be configured to determine that the patterning device is accelerating based on the output signals and/or other information.

In some embodiments, the actuator comprises a rotatable coupling. The rotatable coupling may comprise a rotatable yoke, for example. In some embodiments, the rotatable coupling (e.g., the rotatable yoke) comprises two supports configured to contact the patterning device. The rotatable coupling is configured to rotate in response to the acceleration of the patterning device (e.g., without a need for processors and/or sensors). For example, a center of gravity reaction mass of the rotatable coupling may be aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, thereby counteracting patterning device deformation.

FIG. 11 is a block diagram that illustrates a computer system 1100 that can assist in implementing the methods, flows, or the system(s) disclosed herein. Computer system 1100 includes a bus 1102 or other communication mechanism for communicating information, and a processor 1104 (or multiple processors 1104 and 1105) coupled with bus 1102 for processing information. Computer system 1100 also includes a main memory 1106, such as a random access memory (RAM) or other dynamic storage device, coupled to bus 1102 for storing information and instructions to be executed by processor 1104. Main memory 1106 also may be used for storing temporary variables or other intermediate information during execution of instructions to be executed by processor 1104. Computer system 1100 further includes a read only memory (ROM) 1108 or other static storage device coupled to bus 1102 for storing static information and instructions for processor 1104. A storage device 1110, such as a magnetic disk or optical disk, is provided and coupled to bus 1102 for storing information and instructions.

Computer system 1100 may be coupled via bus 1102 to a display 1112, such as a cathode ray tube (CRT) or flat panel or touch panel display for displaying information to a computer user. An input device 1114, including alphanumeric and other keys, is coupled to bus 1102 for communicating information and command selections to processor 1104. Another type of user input device is cursor control 1116, such as a mouse, a trackball, or cursor direction keys for communicating direction information and command selections to processor 1104 and for controlling cursor movement on display 1112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more flows and/or methods described herein may be performed by computer system 1100 in response to processor 1104 executing one or more sequences of one or more instructions contained in main memory 1106. Such instructions may be read into main memory 1106 from another computer-readable medium, such as storage device 1110. Execution of the sequences of instructions contained in main memory 1106 causes processor 1104 to perform the flows and/or process steps described herein. One or more processors in a multi-processing arrangement may also be employed to execute the sequences of instructions contained in main memory 1106. In an alternative embodiment, hard-wired circuitry may be used in place of or in combination with software instructions. Thus, the description herein is not limited to any specific combination of hardware circuitry and software.

The term “computer-readable medium” or “machine readable medium” as used herein refers to any medium that participates in providing instructions to processor 1104 for execution. Such a medium may take many forms, including but not limited to, non-volatile media, volatile media, and transmission media. Non-volatile media include, for example, optical or magnetic disks, such as storage device 1110. Volatile media include dynamic memory, such as main memory 1106. Transmission media include coaxial cables, copper wire and fiber optics, including the wires that comprise bus 1102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1104 for execution. For example, the instructions may initially be borne on a magnetic disk of a remote computer. The remote computer can load the instructions into its dynamic memory and send the instructions over a telephone line using a modem. A modem local to computer system 1100 can receive the data on the telephone line and use an infrared transmitter to convert the data to an infrared signal. An infrared detector coupled to bus 1102 can receive the data carried in the infrared signal and place the data on bus 1102. Bus 1102 carries the data to main memory 1106, from which processor 1104 retrieves and executes the instructions. The instructions received by main memory 1106 may optionally be stored on storage device 1110 either before or after execution by processor 1104.

Computer system 1100 may also include a communication interface 1118 coupled to bus 1102. Communication interface 1118 provides a two-way data communication coupling to a network link 1120 that is connected to a local network 1122. For example, communication interface 1118 may be an integrated services digital network (ISDN) card or a modem to provide a data communication connection to a corresponding type of telephone line. As another example, communication interface 1118 may be a local area network (LAN) card to provide a data communication connection to a compatible LAN. Wireless links may also be implemented. In any such implementation, communication interface 1118 sends and receives electrical, electromagnetic, or optical signals that carry digital data streams representing various types of information.

Network link 1120 typically provides data communication through one or more networks to other data devices. For example, network link 1120 may provide a connection through local network 1122 to a host computer 1124 or to data equipment operated by an Internet Service Provider (ISP) 1126. ISP 1126 in turn provides data communication services through the worldwide packet data communication network, now commonly referred to as the “Internet” 1128. Local network 1122 and Internet 1128 both use electrical, electromagnetic, or optical signals that carry digital data streams. The signals through the various networks and the signals on network link 1120 and through communication interface 1118, which carry the digital data to and from computer system 1100, are exemplary forms of carrier waves transporting the information.

Computer system 1100 can send messages and receive data, including program code, through the network(s), network link 1120, and communication interface 1118. In the Internet example, a server 1130 might transmit a requested code for an application program through Internet 1128, ISP 1126, local network 1122 and communication interface 1118. One such downloaded application may provide all or part of a method described herein, for example. The received code may be executed by processor 1104 as it is received, and/or stored in storage device 1110, or other non-volatile storage for later execution. In this manner, computer system 1100 may obtain application code in the form of a carrier wave.

Various embodiments of the present systems and methods are disclosed in the subsequent list of numbered clauses:
1. A clamping system, comprising: a vacuum clamp configured to apply a clamping force to a patterning device to clamp the patterning device during acceleration; and an actuator configured to apply an actuation force to the patterning device to reduce or eliminate deformation imparted to the patterning device during the acceleration, the actuator configured to apply the actuation force responsive to the acceleration.
2. The system of clause 1, wherein the actuation force is in a direction substantially perpendicular to a direction of the acceleration.
3. The system of any of the previous clauses, wherein the patterning device comprises a reticle.
4. The system of any of the previous clauses, wherein the deformation imparted to the patterning device during acceleration comprises twist deformation.
5. The system of any of the previous clauses, wherein: the patterning device has a rectangular shape, the vacuum clamp further comprises two supports for a first side of the patterning device and one support for a second side of the patterning device, the twist deformation occurs on the second side of patterning device, and the actuation force is configured to reduce or eliminate the twist deformation on the second side of the patterning device.
6. The system of any of the previous clauses, wherein the actuation force applied by the actuator does not suppress deformation due to frictional forces from the vacuum clamp caused by the acceleration.
7. The system of any of the previous clauses, wherein the vacuum clamp comprises a reticle vacuum clamp for a deep ultraviolet (DUV) lithography apparatus.
8. The system of any of the previous clauses, wherein the actuator is configured such that the actuation force comprises a pushing force configured to be applied to a first portion of the patterning device, and a pulling force configured to be applied to a second portion of the patterning device.
9. The system of any of the previous clauses, wherein the vacuum clamp comprises a vacuum pad, and wherein the actuator is configured to act on the pad such that the pad applies the actuation force to the patterning device, or the actuator is configured to act directly on the patterning device to apply the actuation force.
10. The system of any of the previous clauses, wherein the actuator is a Lorentz force based actuator.
11. The system of any of the previous clauses, wherein the actuator is a piezoelectric actuator.
12. The system of any of the previous clauses, wherein the actuator is an air pump configured to pressurize a gap between the patterning device and a vacuum pad of the vacuum clamp; or an air pump or air bearing configured to act on the vacuum pad, between the vacuum pad and a reticle chuck.
13. The system of any of the previous clauses, wherein the air pump is configured to cause a pressure gradient in the gap such that a pushing force is applied to a first portion of the patterning device, and a pulling force is applied to a second portion of the patterning device, the pushing force and the pulling force together comprising the actuation force.
14. The system of any of the previous clauses, further comprising one or more processors, the one or more processors configured by machine-readable instructions to determine that the patterning device is accelerating, and responsive to a determination of acceleration, cause the actuator to apply the actuation force to the patterning device to reduce or eliminate the deformation imparted to the patterning device.
15. The system of any of the previous clauses, further comprising one or more sensors configured to generate output signals conveying information related to the acceleration of the patterning device.
16. The system of any of the previous clauses, wherein the one or more processors are configured to determine that the patterning device is accelerating based on the output signals.
17. The system of any of the previous clauses, wherein the actuator comprises a rotatable coupling.
18. The system of any of the previous clauses, wherein the rotatable coupling comprises a rotatable yoke.
19. The system of any of the previous clauses, wherein the rotatable coupling comprises two supports configured to contact the patterning device, and wherein the rotatable coupling is configured to rotate in response to the acceleration of the patterning device.
20. The system of any of the previous clauses, wherein a center of gravity reaction mass of the rotatable coupling is aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, thereby counteracting patterning device deformation.
21. A clamping method, comprising: applying, with a vacuum clamp, a clamping force to a patterning device to clamp the patterning device during acceleration; and applying, with an actuator, an actuation force to the patterning device to reduce or eliminate deformation imparted to the patterning device during the acceleration, the actuator configured to apply the actuation force responsive to the acceleration.
22. The method of clause 21, wherein the actuation force is in a direction substantially perpendicular to a direction of the acceleration.
23. The method of any of the previous clauses, wherein the patterning device comprises a reticle.
24. The method of any of the previous clauses, wherein the deformation imparted to the patterning device during acceleration comprises twist deformation.
25. The method of any of the previous clauses, wherein: the patterning device has a rectangular shape, the vacuum clamp comprises two supports for a first side of the patterning device and one support for a second side of the patterning device, the twist deformation occurs on the second side of patterning device, and the actuation force is configured to reduce or eliminate the twist deformation on the second side of the patterning device.
26. The method of any of the previous clauses, wherein the actuation force applied by the actuator does not suppress deformation due to frictional forces from the vacuum clamp caused by the acceleration.
27. The method of any of the previous clauses, wherein the vacuum clamp comprises a reticle vacuum clamp for a deep ultraviolet (DUV) lithography apparatus.
28. The method of any of the previous clauses, wherein the actuator is configured such that the actuation force comprises a pushing force configured to be applied to a first portion of the patterning device, and a pulling force configured to be applied to a second portion of the patterning device.
29. The method of any of the previous clauses, wherein the vacuum clamp comprises a vacuum pad, and wherein the actuator is configured to act on the pad such that the pad applies the actuation force to the patterning device, or the actuator is configured to act directly on the patterning device to apply the actuation force.
30. The method of any of the previous clauses, wherein the actuator is a Lorentz force based actuator.
31. The method of any of the previous clauses, wherein the actuator is a piezoelectric actuator.
32. The method of any of the previous clauses, wherein the actuator is an air pump configured to pressurize a gap between the patterning device and a vacuum pad of the vacuum clamp; or an air pump or air bearing configured to act on the vacuum pad, between the vacuum pad and a reticle chuck.
33. The method of any of the previous clauses, wherein the air pump is configured to cause a pressure gradient in the gap such that a pushing force is applied to a first portion of the patterning device, and a pulling force is applied to a second portion of the patterning device, the pushing force and the pulling force together comprising the actuation force.
34. The method of any of the previous clauses, further comprising determining, with one or more processors configured by machine-readable instructions, that the patterning device is accelerating, and responsive to a determination of acceleration, causing the actuator to apply the actuation force to the patterning device to reduce or eliminate the deformation imparted to the patterning device.
35. The method of any of the previous clauses, further comprising generating, with one or more sensors, output signals conveying information related to the acceleration of the patterning device.
36. The method of any of the previous clauses, wherein the one or more processors are configured to determine that the patterning device is accelerating based on the output signals.
37. The method of any of the previous clauses, wherein the actuator comprises a rotatable coupling.
38. The method of any of the previous clauses, wherein the rotatable coupling comprises a rotatable yoke.
39. The method of any of the previous clauses, wherein the rotatable coupling comprises two supports configured to contact the patterning device, and wherein the rotatable coupling is configured to rotate in response to the acceleration of the patterning device.
40. The method of any of the previous clauses, wherein a center of gravity reaction mass of the rotatable coupling is aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, thereby counteracting patterning device deformation.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments. For example, the inspection system, and the associated software may comprise separate embodiments, and/or these features may be used together in the same embodiment.

The descriptions above are intended to be illustrative, not limiting. Thus, it will be apparent to one skilled in the art that modifications may be made as described without departing from the scope of the claims set out below.

1. A clamping system, comprising:
a clamp configured to apply a clamping force to a patterning device to clamp the patterning device during acceleration; and
an actuator configured to apply an actuation force to the patterning device to reduce deformation imparted to the patterning device during the acceleration, the actuator configured to apply the actuation force responsive to the acceleration.

2. The system of claim 1, wherein the actuation force is in a direction substantially perpendicular to a direction of the acceleration.

3. The system of claim 1, wherein the actuation force applied by the actuator does not suppress deformation due to frictional forces from the clamp caused by the acceleration.

4. The system of claim 1, wherein the clamp comprises a vacuum pad and wherein the actuator is configured to act on the pad such that the pad applies the actuation force to the patterning device.

5. The system of claim 1, wherein:
the actuator is an air pump configured to pressurize a gap between the patterning device and a vacuum pad of the clamp of a reticle chuck; or an air pump or air bearing configured to act on the vacuum pad, between the vacuum pad and a reticle chuck; and
the air pump is configured to cause a pressure gradient between the patterning device and the reticle chuck such that a pushing force is applied to a first portion of the patterning device, and a pulling force is applied to a second portion of the patterning device, the pushing force and the pulling force together comprising the actuation force.

6. The system of claim 1, further comprising:
one or more processors configured by machine-readable instructions to determine that the patterning device is accelerating, and responsive to a determination of acceleration, cause the actuator to apply the actuation force to the patterning device to reduce the deformation imparted to the patterning device; and
one or more sensors configured to generate output signals conveying information related to the acceleration of the patterning device, wherein the one or more processors are configured to determine that the patterning device is accelerating based on the output signals.

7. The system of claim 1, wherein:
the actuator comprises a rotatable coupling;
the rotatable coupling comprises a rotatable yoke;
the rotatable coupling is configured to rotate in response to the acceleration of the patterning device; and
a center of gravity reaction mass of the rotatable coupling is aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, to counteract patterning device deformation.

8. A clamping method, comprising:
applying, with a clamp, a clamping force to a patterning device to clamp the patterning device during acceleration; and
applying, with an actuator, an actuation force to the patterning device to reduce deformation imparted to the patterning device during the acceleration, the actuator configured to apply the actuation force responsive to the acceleration.

9. The method of claim 8, wherein the actuation force is in a direction substantially perpendicular to a direction of the acceleration.

10. The method of claim 8, wherein:
the actuation force applied by the actuator does not suppress deformation due to frictional forces from the clamp caused by the acceleration; or
the actuation force comprises a pushing force configured to be applied to a first portion of the patterning device, and a pulling force configured to be applied to a second portion of the patterning device

11. The method of claim 8, wherein the clamp comprises a vacuum pad, and wherein the actuator acts on the pad such that the pad applies the actuation force to the patterning device.

12. The method of claim 8, wherein:
the actuator is an air pump configured to pressurize a gap between the patterning device and a vacuum pad of the clamp of a reticle chuck; or an air pump or air bearing configured to act on the vacuum pad, between the vacuum pad and a reticle chuck; and
the air pump causes a pressure gradient between the patterning device and the reticle chuck such that a pushing force is applied to a first portion of the patterning device, and a pulling force is applied to a second portion of the patterning device, the pushing force and the pulling force together comprising the actuation force.

13. The method of claim 8, further comprising:
determining, that the patterning device is accelerating, and responsive to a determination of acceleration, causing the actuator to apply the actuation force to the patterning device to reduce the deformation imparted to the patterning device; and
generating, with one or more sensors, output signals conveying information related to the acceleration of the patterning device, wherein the determination that the patterning device is accelerating is based on the output signals.

14. The method of claim 8, wherein:
the actuator comprises a rotatable coupling;
the rotatable coupling comprises a rotatable yoke;
the rotatable coupling rotates in response to the acceleration of the patterning device; and
a center of gravity reaction mass of the rotatable coupling is aligned with a pivot point reaction mass of the rotatable coupling, and spaced from the pivot point reaction mass by a target distance along an axis of rotation, such that during acceleration of the patterning device, inertia of the rotatable coupling causes rotation of the rotatable coupling around the pivot point reaction mass and the axis of rotation, to counteract patterning device deformation.

15. The method of claim 8, wherein the deformation imparted to the patterning device during acceleration comprises twist deformation.

16. The method of claim 8, wherein:
the clamp comprises two supports for a first side of the patterning device and one support for a second side of the patterning device;
the twist deformation occurs on the second side of patterning device; and
the actuation force is configured to reduce the twist deformation on the second side of the patterning device

17. The system of claim 1, wherein the deformation imparted to the patterning device during acceleration comprises twist deformation.

18. The system of claim 17, wherein:
the clamp further comprises two supports for a first side of the patterning device and one support for a second side of the patterning device;
the twist deformation occurs on the second side of patterning device; and
the actuation force is configured to reduce the twist deformation on the second side of the patterning device.

19. The system of claim 1, wherein the actuator is configured such that the actuation force comprises a pushing force configured to be applied to a first portion of the patterning device, and a pulling force configured to be applied to a second portion of the patterning device.

20. The system of claim 1, wherein the actuator is configured to act directly on the patterning device to apply the actuation force.
